(19) United States
(12) Patent Application Publication
(10) Pub. No.: US 2025/0268076 A1
(43) Pub. Date: Aug. 21, 2025

(54) DISPLAY APPARATUS HAVING OPTICAL LENSES

(71) Applicant: LG Display Co., Ltd., Seoul (KR)

(72) Inventors: Ju Seong PARK, Paju-si (KR); Joung Won WOO, Paju-si (KR); Wook JEON, Paju-si (KR)

(21) Appl. No.: 18/936,206

(22) Filed: Nov. 4, 2024

(30) Foreign Application Priority Data
Feb. 15, 2024 (KR) 10-2024-0021723

(51) Int. Cl. H10K 59/80

(52) U.S. Cl. CPC H10K 59/879; H10K 59/8792

(57) ABSTRACT

A display apparatus including optical lenses is provided. The display apparatus can include light-emitting devices disposed on emission areas of a device substrate. The light emitted from each emission area can display a different color from the light emitted from adjacent emission area. An optical insulating layer and color filters can be disposed on the light-emitting devices. Each of the color filters can overlap a plurality of emission areas. Each of the optical lenses can overlap one of the color filters. Thus, in the display apparatus, the light emitted from some of the plurality of emission areas overlapping with each optical lens can be blocked by the color filter overlapping with the corresponding optical lens. Therefore, in the display apparatus, the field of view (FOV) in which an image is three-dimensionally recognized by a user can be increased.

### CROSS-REFERENCE TO RELATED APPLICATIONS

This application claims the benefit of Korean Patent Application No. 10-2024-0021723, filed on Feb. 15, 2024, which is hereby incorporated by reference as if fully set forth herein.

### BACKGROUND

### Technical Field

The present disclosure relates to a display apparatus in which optical lenses are disposed on light-emitting devices.

### Description of the Related Art

Generally, a display apparatus provides an image to a user. For example, the display apparatus can include light-emitting devices. Each of the light-emitting devices can emit light displaying a specific color. For example, each of the light-emitting devices can include a light-emitting layer disposed between a first electrode and a second electrode.

The image provided by the display apparatus can be three-dimensionally recognized by the user. For example, the display apparatus can include optical lenses disposed on the light-emitting devices. A size of each optical lens can be a greater than a size of each light-emitting device. For example, each of the optical lenses can overlap a plurality of light-emitting device. The light generated by each light-emitting device can display a different color from the light generated by adjacent light-emitting device.

The field of view (FOV) region in which the user three-dimensionally recognizes the image can be determined by a pitch of the optical lenses and a distance between the light-emitting devices and the optical lenses. For example, the FOV region in which the user three-dimensionally recognizes the image can be proportional to a distance between the optical lenses through which the light emitted from a single light-emitting device passes.

### BRIEF SUMMARY

In the display apparatus, when a horizontal width of each optical lens is adjusted, the image provided to the user can be repeatedly generated. The inventors of the present disclosure have appreciated that, in the aforementioned display apparatus, the quality of the image recognized by the user can be decreased. And, in the display apparatus, when the distance between the light-emitting devices and the optical lenses is increased to prevent the repeated generation of the images, the FOV region in which the image is three-dimensionally recognized by the user can be reduced. Accordingly, the present disclosure is directed to a display apparatus that substantially obviates one or more problems due to limitations and disadvantages of the related art.

Various embodiments of the present disclosure provide a display apparatus capable of increasing the region in which the image is three-dimensionally recognized by the user.

Various embodiments of the present disclosure provide a display apparatus capable of increasing the distance between the optical lenses through with the light emitted from a single light-emitting device passes, without the decrease in the quality of the image recognized by the user.

Additional advantages, technical benefits, and features of the disclosure will be set forth in part in the description which follows and in part will become apparent to those having ordinary skill in the art upon examination of the following or can be learned from practice of the disclosure. The benefits and other advantages of the disclosure can be realized and attained by the structure particularly pointed out in the written description and claims hereof as well as the appended drawings.

According to one embodiment, a display apparatus includes a device substrate is provided. The display apparatus includes a first light-emitting device is disposed on a first emission area of the device substrate. The display apparatus includes a second light-emitting device is disposed on a second emission area of the device substrate. The light emitted from the second emission area displays a different color from the light emitted from the first emission area. The display apparatus includes an optical insulating layer is disposed on the first light-emitting device and the second light-emitting device. The display apparatus includes an optical structure is disposed on the optical insulating layer. The optical structure includes a first curved surface of a convex shape. The first curved surface overlaps the first emission area and the second emission area. The optical structure includes at least one of dye and pigment.

The light passing through the optical structure can display a same color as the light emitted from the first emission area.

The optical structure can include a first optical lens having the first curved surface. The dye and the pigment can be dispersed in the first optical lens.

The optical structure can include a lens planarization layer. The first curved surface of the first optical lens can be covered by the lens planarization layer. The refractive index of the lens planarization layer can be smaller than the refractive index of the first optical lens.

A third light-emitting device can be disposed between a third emission area of the device substrate and the optical insulating layer. The optical insulating layer includes a second optical lens overlapping with the third emission area. A second curved surface of the second optical lens can have a same shape as the first curved surface of the first optical lens. The light passing through the second optical lens can display a different color from the light passing through the first optical lens.

The light emitted from the third emission area can display a different color from the light emitted from the first emission area and the light emitted from the second emission area. The light passing through the second optical lens can display a same color as the light emitted from the second emission arca.

A black matrix can be disposed between the first optical lens and the second optical lens.

The first curved surface can have a convex shape toward a direction opposite to the device substrate.

In another embodiment, there is provided a display apparatus comprising a device substrate. Light-emitting devices are disposed on emission areas of the device substrate. The light generated by each light-emitting device displays a different color from the light generated by adjacent light-emitting device. An optical insulating layer is disposed on the light-emitting devices. A color filter and an optical lens area disposed on the optical insulating layer. The color filter overlaps the emission areas. The optical lens overlaps the color filter. The light passing through the color filter can display a same color as the light generated by one of the light-emitting devices.

A surface of the optical lens toward the color filter can be in contact with the color filter.

The emission areas can be disposed side by side in a first direction and a second direction. The second direction can be perpendicular to the first direction. The color filter and the optical lens can extend parallel to each other in a direction inclined with the first direction and the second direction.

The length of the color filter in the first direction can be different from the length of the optical lens in the first direction.

A lens planarization layer can be disposed between the optical insulating layer and the optical lens. The optical lens can be disposed between the lens planarization layer and the color filter. The optical lens can have a curved surface of a convex shape contacting with the lens planarization layer. The refractive index of the lens planarization layer can be smaller than the refractive index of the optical lens.

A cover substrate can be disposed on the color filter.

A region disposed between the emission areas can overlap a portion of the optical lens.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is an enlarged view of K region in FIG. 1;

FIG. 4 is a view taken along I-I′ of FIG. 3;

FIG. 5 is an enlarged view of R region in FIG. 4;

FIGS. 6A and 6B are graphs showing angle in which the image is recognized in a display apparatus without color filters overlapping with optical lenses and the display apparatus according to the embodiment of the present disclosure; and

FIGS. 7 to 9 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element so as to come into contact with the second element, a third element can be interposed between the first element and the second element.

The text “at least one of A and B” as used herein should be understood to include at least one of A, or at least one of B, or at least one of both A and B. This similarly applies to “at least one of A, B, and C” and so forth.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

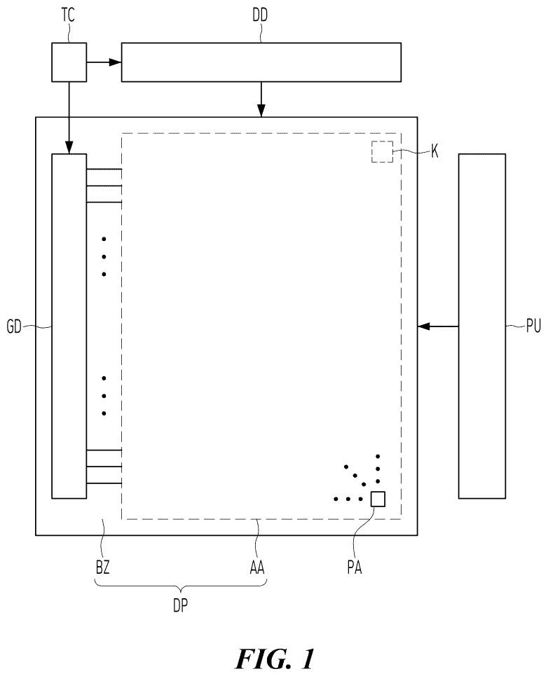

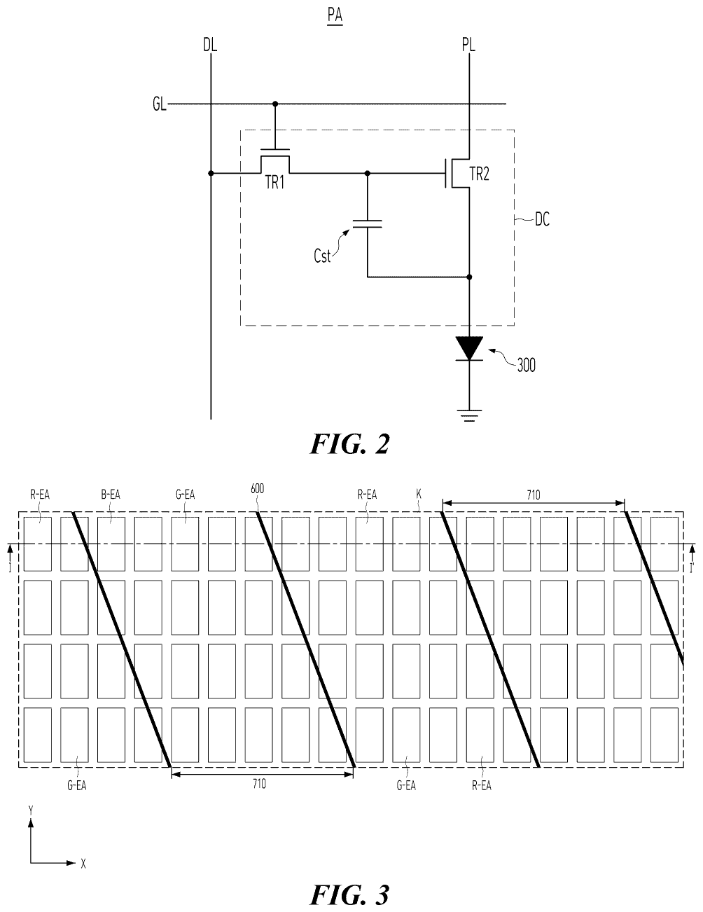

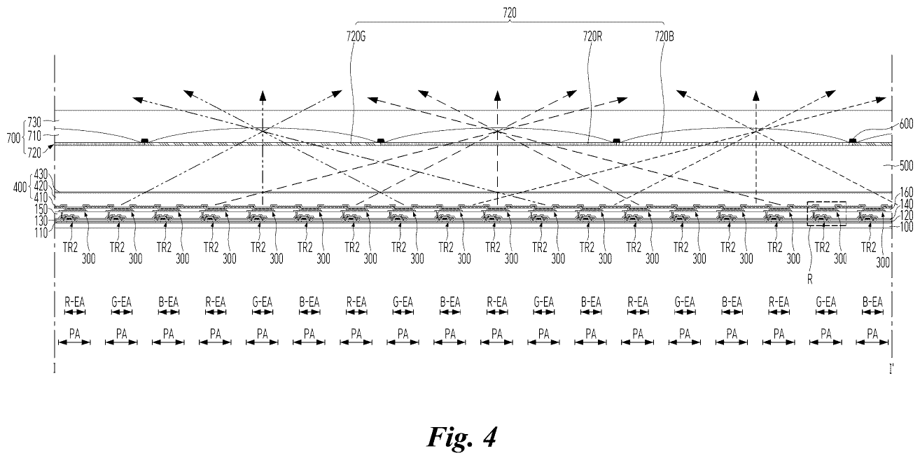

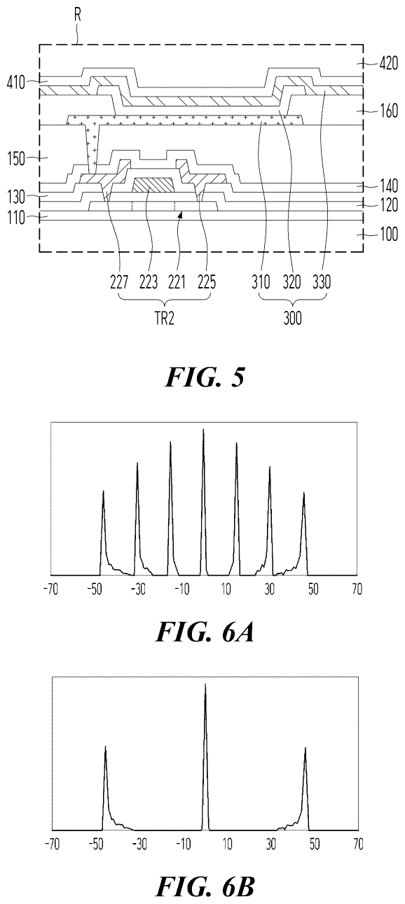

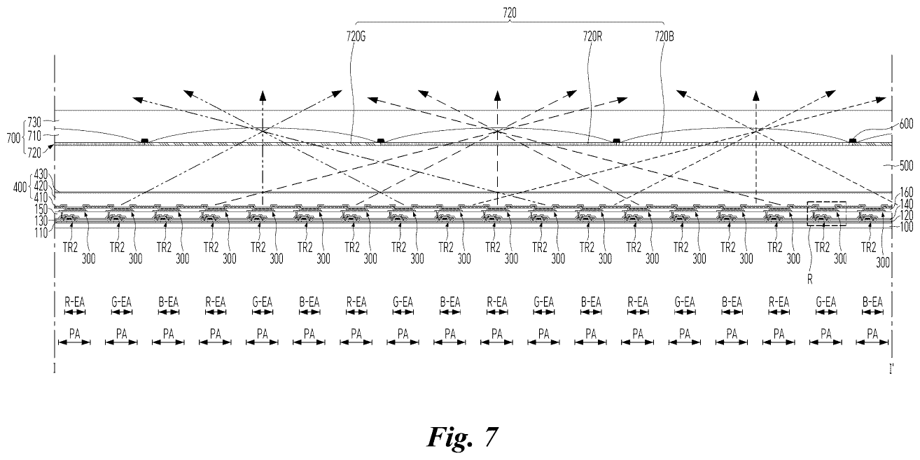

FIG. 1 is a view schematically showing a display apparatus according to an embodiment of the present disclosure. FIG. 2 is a view showing a circuit of a pixel area in the display apparatus according to the embodiment of the present disclosure. FIG. 3 is an enlarged view of K region in FIG. 1. FIG. 4 is a view taken along I-I′ of FIG. 3. FIG. 5 is an enlarged view of R region in FIG. 4.

Referring to FIGS. 1 to 5, the display apparatus according to the embodiment of the present disclosure can include a display panel DP. The display panel DP can generate an image provided to a user. For example, pixel areas PA can be disposed in the display panel DP. Various signals can be provided in each pixel area PA through signal wirings GL, DL and PL. For example, the signal wirings GL, DL and PL can include gate lines GL applying a gate signal, data lines DL applying a data signal, and power voltage supply lines PL supplying a power voltage.

The gate lines GL can be electrically connected to a gate driver GD. The data lines DL can be electrically connected to a data driver DD. The gate driver GD and the data driver DD can be controlled by a timing controller TC. For example, the gate driver GD can receive clock signals, reset signals and a start signal from the timing controller TC, and the data driver DD can receive digital video data and a source timing signal from the timing controller TC. The power voltage supply lines PL can be electrically connected to a power unit PU.

The display panel DP can include an active area AA in which the pixel areas PA are disposed, and a bezel area BZ being disposed outside the active area AA. The bezel area BZ can be disposed outside the pixel areas PA. For example, the active area AA can be surrounded by the bezel arca BZ. The gate driver GD, the data driver DD, the timing controller TC and the power unit PU can be disposed outside the active area AA. For example, each of the signal wirings GL, DL and PL can include a region disposed on the bezel area BZ.

At least one of the gate driver GD, the data driver DD, the timing controller TC and the power unit PU can be disposed on the bezel area BZ. For example, the display apparatus according to the embodiment of the present disclosure can be a GIP (Gate In Panel) type display apparatus in which the gate driver GD is formed on the bezel area BZ.

Each of the pixel areas PA can emit light displaying a specific color according to the signal applied through the signal wirings GL, DL and PL. For example, a driving circuit DC electrically connected to a light-emitting device 300 can be disposed in each pixel area PA. The driving circuit DC of each pixel area PA can control the light-emitting device 300 of the corresponding pixel area PA according to signals applied to the signal wirings GL, DL and PL. For example, the driving circuit DC of each pixel area PA can supply a driving current corresponding to the data signal to the light-emitting device 300 of the corresponding pixel area PA according to the gate signal. The driving current supplied by the driving circuit DC of each pixel area PA can be maintained for one frame. For example, the driving circuit DC of each pixel area PA can include a first thin film transistor TR1, a second thin film transistor TR2 and a storage capacitor Cst.

The first thin film transistor TR1 of each pixel area PA can transmit the data signal to the second thin film transistor TR2 of the corresponding pixel area PA according to the gate signal. For example, the first thin film transistor TR1 of each pixel area PA can function as a switching thin film transistor. The first thin film transistor TR1 of each pixel area PA can include a first semiconductor pattern, a first gate electrode, a first drain electrode and a first source electrode. For example, the first gate electrode of each pixel area PA can be electrically connected to the corresponding gate line GL, and the first drain electrode of each pixel area PA can be electrically connected to the corresponding date line DL.

The first semiconductor pattern can include a semiconductor material. For example, the first semiconductor pattern can include Low-Temperature Poly-Si (LTPS) or an oxide semiconductor, such as IGZO. The first semiconductor pattern can include a first drain region, a first channel region and a first source region. The first channel region can be disposed between the first drain region and the first source region. The first drain region and the first source region can have a resistance smaller than the first channel region. For example, the first drain region and the first source region can include a conductive region of an oxide semiconductor. The first channel region can be a region of an oxide semiconductor, which is not conductorized.

The first gate electrode can be disposed on a portion of the first semiconductor pattern. For example, the first gate electrode can overlap the first channel region of the first semiconductor pattern. The first drain region and the first source region of the first semiconductor pattern can be disposed outside the first gate electrode. The first gate electrode can include a conductive material. For example, the first gate electrode can include a metal, such as aluminum (Al), chrome (Cr), copper (Cu), molybdenum (Mo), titanium (Ti) and tungsten (W). The first gate electrode can be spaced apart from the first semiconductor pattern. The first gate electrode can be insulated from the first semiconductor pattern. For example, the first drain region of the first semiconductor pattern can be electrically connected to the first source region of the first semiconductor pattern according to a signal applied to the first gate electrode.

The first drain electrode can include a conductive material. For example, the first drain electrode can include a metal, such as aluminum (Al), chrome (Cr), copper (Cu), molybdenum (Mo), titanium (Ti) and tungsten (W). The first drain electrode can include a different material from the first gate electrode. For example, the first drain electrode can be disposed on a different layer from the first gate electrode. The first drain electrode can be electrically connected to the first drain region of the first semiconductor pattern. The first drain electrode can be insulated from the first gate electrode.

The first source electrode can include a conductive material. For example, the first source electrode can include a metal, such as aluminum (Al), chrome (Cr), copper (Cu), molybdenum (Mo), titanium (Ti) and tungsten (W). The first source electrode can include a different material from the first gate electrode. The first source electrode can be disposed on a different layer from the first gate electrode. For example, the first source electrode can be disposed on a same layer as the first drain electrode. The first source electrode can include a same material as the first drain electrode. The first source electrode can be formed by a same process as the first drain electrode. For example, the first source electrode can be formed simultaneously with the first drain electrode. The first source electrode can be electrically connected to the first source region of the first semiconductor pattern. The first source electrode can be insulated from the first gate electrode. The first source electrode can be spaced apart from the first drain electrode.

The second thin film transistor TR2 of each pixel area PA can generate the driving current corresponding to the data signal. For example, the second thin film transistor TR2 of each pixel area PA can function as a driving thin film transistor. The second thin film transistor TR2 of cach pixel area PA can include a second semiconductor pattern 221, a second gate electrode 223, a second drain electrode 225 and a second source electrode 227. For example, the second gate electrode 223 of each pixel area PA can be electrically connected to the first source electrode of the corresponding pixel area PA, and the second drain electrode 225 of each pixel area PA can be electrically connected to the corresponding power voltage supply line PL.

The second semiconductor pattern 221 can include a semiconductor material. For example, the second semiconductor pattern 221 can include Low-Temperature Poly-Si (LTPS) or an oxide semiconductor, such as IGZO. The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second semiconductor pattern 221 can include a second drain region, a second channel region and a second source region. The second channel region can be disposed between the second drain region and the second source region. The second drain region and the second source region can have a resistance smaller than the second channel region. For example, the second drain region and the second source region can include a conductive region of an oxide semiconductor. The second channel region can be a region of an oxide semiconductor, which is not conductorized.

The second gate electrode 223 can be disposed on a portion of the second semiconductor pattern 221. For example, the second gate electrode 223 can overlap the second channel region of the second semiconductor pattern 221. The second drain region and the second source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the second channel region of the second semiconductor pattern 221 can have an electrical conductivity corresponding to a voltage applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. For example, the second drain electrode 225 can be disposed on a different layer from the second gate electrode 223. The second drain electrode 225 can be electrically connected to the second drain region of the second semiconductor pattern 221. The second drain electrode 225 can be insulated from the second gate electrode 223.

The second drain electrode 225 can be disposed on a same layer as the first drain electrode. The second drain electrode 225 can include a same material as the first drain electrode. The second drain electrode 225 can be formed by a same process as the first drain electrode. For example, the second drain electrode 225 can be formed simultaneously with the first drain electrode.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be disposed on a different layer from the second gate electrode 223. For example, the second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be electrically connected to the second source region of the second semiconductor pattern 221. The second source electrode 227 can be insulated from the second gate electrode 223. The second source electrode 227 can be spaced apart from the second drain electrode 225.

The storage capacitor Cst of each pixel area PA can maintain a voltage applied to the second gate electrode 223 of the corresponding pixel area PA for one frame. For example, the storage capacitor Cst of each pixel area PA can be electrically connected to the second gate electrode 223 and the second source electrode 227 of the corresponding pixel area PA. The storage capacitor Cst of each pixel area PA can have a stacked structure of capacitor electrodes. For example, the storage capacitor Cst of each pixel area PA can include a first capacitor electrode electrically connected to the second gate electrode 233 of the corresponding pixel area PA, and a second capacitor electrode electrically connected to the second source electrode 227 of the corresponding pixel arca PA.

The first capacitor electrode and the second capacitor electrode of each pixel area PA can be formed by using a process of forming the first thin film transistor TR1 and the second thin film transistor TR2 in the corresponding pixel area PA. For example, the first capacitor electrode of each pixel area PA can be disposed on a same layer as the second gate electrode 223 of the corresponding pixel area PA, and the second capacitor electrode of each pixel area PA can be disposed on a same layer as the second source electrode 227 of the corresponding pixel area PA. The first capacitor electrode of each pixel area PA can include a same material as the second gate electrode 223 of the corresponding pixel area PA, and the second capacitor electrode of each pixel acra PA can include a same material as the second source electrode 227 of the corresponding pixel area PA. The first capacitor electrode of each pixel area PA can be formed by a same process as the second gate electrode 223 of the corresponding pixel area PA, and the second capacitor electrode of each pixel area PA can be formed by a same process as the second source electrode 227 of the corresponding pixel area PA. For example, the first capacitor electrode of each pixel area PA can be formed simultaneously with the second gate electrode 223 of the corresponding pixel area PA, and the second capacitor electrode of each pixel area PA can be formed simultaneously with the second source electrode 227 of the corresponding pixel area PA. Thus, in the display apparatus according to the embodiment of the present disclosure, a process of forming the driving circuit DC in each pixel arca PA can be simplified.

The light-emitting device 300 and the driving circuit DC of each pixel area PA can be supported by a device substrate 100. For example, the light-emitting device 300 and the driving circuit DC of each pixel area PA can be disposed on the device substrate 100. The device substrate 100 can include an insulating material. For example, the device substrate 100 can include glass or plastic.

A plurality of insulating layers 110, 120, 130, 140, 150 and 160 for preventing unnecessary electrical connection can be disposed on the device substrate 100. For example, a buffer insulating layer 110, a gate insulating layer 120, an interlayer insulating layer 130, a device passivation layer 140, a planarization layer 150 and a bank insulating layer 160 can be disposed on the device substrate 100.

The buffer insulating layer 110 can be disposed on the device substrate 100. The buffer insulating layer 110 can prevent the pollution due to the device substrate 100 in a process of forming the driving circuit DC of each pixel area PA. For example, the buffer insulating layer 110 can extend along an upper surface of the device substrate 100 toward the driving circuit DC of each pixel area PA. The driving circuit DC of each pixel area PA can be disposed on the buffer insulating layer 110. The buffer insulating layer 110 can include an insulating material. For example, the buffer insulating layer 110 can include an inorganic insulating material, such as silicon oxide (SiOx) and silicon nitride (SiNx). The buffer insulating layer 110 can have a multi-layer structure. For example, the buffer insulating layer 110 can have a structure in which an inorganic insulating layer made of silicon oxide (SiOx) and an inorganic insulating layer made of silicon nitride (SiNx) are stacked.

The gate insulating layer 120 can be disposed on the buffer insulating layer 110. The first gate electrode of each pixel area PA can be insulated from the first semiconductor pattern of the corresponding pixel area PA by the gate insulating layer 120. The second gate electrode 223 of each pixel area PA can be insulated from the second semiconductor pattern 221 of the corresponding pixel arca PA by the gate insulating layer 120. For example, the gate insulating layer 120 can cover the first semiconductor pattern and the second semiconductor pattern 221 of each pixel arca PA. The first gate electrode and the second gate electrode 223 of each pixel area PA can be disposed on the gate insulating layer 120. The gate insulating layer 120 can include an insulating material. For example, the gate insulating layer 120 can include an inorganic insulating material, such as silicon oxide (SiOx) and silicon nitride (SiNx).

The interlayer insulating layer 130 can be disposed on the gate insulating layer 120. The first drain electrode and the first source electrode of each pixel area PA can be insulated from the first gate electrode of the corresponding pixel area PA by the interlayer insulating layer 130. The second drain electrode 225 and the second source electrode 227 of each pixel area PA can be insulated from the second gate electrode 223 of the corresponding pixel area PA by the interlayer insulating layer 130. For example, the interlayer insulating layer 130 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 130. The interlayer insulating layer 130 can include an insulating material. For example, the interlayer insulating layer 130 can include an inorganic insulating material.

The device passivation layer 140 can be disposed on the interlayer insulating layer 130. The device passivation layer 140 can prevent the damage of the driving circuit DC in each pixel area PA due to external impact and moisture. For example, the first drain electrode, the first source electrode, the second drain electrode 225 and the second source electrode 227 of each pixel arca PA can be covered by the device passivation layer 140. The device passivation layer 140 can extend beyond the driving circuit DC in each pixel area PA. The device passivation layer 140 can include an insulating material. For example, the device passivation layer 140 can be a linear insulating layer made of an inorganic insulating material.

The planarization layer 150 can be disposed on the device passivation layer 140. The planarization layer 150 can remove a thickness difference due to the driving circuit DC of each pixel area PA. For example, an upper surface of the planarization layer 150 opposite to the device substrate 100 can be a flat. The upper surface of the planarization layer 150 can be parallel to the upper surface of the device substrate 100. The planarization layer 150 can include an insulating material. The planarization layer 150 can include a different material from the device passivation layer 140. The planarization layer 150 can include a material having a relatively high fluidity. For example, the planarization layer 150 can include an organic insulating material.

The light-emitting device 300 of each pixel area PA can be disposed on the planarization layer 150. The light-emitting device 300 of each pixel area PA can emit light displaying a specific color. For example, the light-emitting device 300 of each pixel area PA can include a first electrode 310, a light-emitting layer 320 and a second electrode 330, which are sequentially stacked on the planarization layer 150 of the corresponding pixel area PA.

The first electrode 310 can include a conductive material. The first electrode 310 can include a material having a relatively high reflectance. For example, the first electrode 310 can include a metal, such as aluminum (Al) and silver (Ag). The first electrode 310 can have a multi-layer structure. For example, the first electrode 310 can have a structure in which a reflective electrode made of a metal is disposed between transparent electrodes made of a transparent conductive material, such as ITO and IZO.

The light-emitting layer 320 can generate light having luminance corresponding to a voltage difference between the first electrode 310 and the second electrode 330. For example, the light-emitting layer 320 can include at least one emission material layer (EML). The emission material layer can include an organic emission material, an inorganic emission material, or a hybrid emission material. For example, the display apparatus according to the embodiment of the present disclosure can be an organic light-emitting display apparatus including an organic emission material.

The light-emitting layer 320 can have a multi-layer structure. For example, the light-emitting layer 320 can include at least one of a hole injection layer (HIL), a hole transport layer (HTL), an electron transport layer (ETL) and an electron injection layer (EIL). Thus, in the display apparatus according to the embodiment of the present disclosure, the emission efficiency of the light-emitting layer 320 can be improved.

The second electrode 330 can include a conductive material. The second electrode 330 can include a different material from the first electrode 310. A transmittance of the second electrode 330 can be greater than a transmittance of the first electrode 310. For example, the second electrode 330 can be a transparent electrode made of a transparent conductive material, such as ITO and IZO. Thus, in the display apparatus according to the embodiment of the present disclosure, the light generated by the light-emitting layer 320 can be emitted through the second electrode 330. The second electrode 330 can have a work-function smaller than the first electrode 310. For example, the first electrode 310 can function as anode electrode, and the second electrode 330 can function as cathode electrode.

The bank insulating layer 160 can be disposed on the planarization layer 150. The first electrode 310 of each pixel area PA can be insulated from the first electrode 310 of adjacent pixel area PA by the bank insulating layer 160. For example, an edge of the first electrode 310 in each pixel area PA can be covered by the bank insulating layer 160. The bank insulating layer 160 can define an emission area R-EA, G-EA and B-EA in each pixel area PA. For example, the first electrode 310 of each pixel area PA can be partially exposed by the bank insulating layer 160. The light-emitting layer 320 and the second electrode 330 of each pixel area PA can be stacked on a portion of the corresponding first electrode 310 overlapping with the emission arca R-EA, G-EA and B-EA of the corresponding pixel area PA. For example, the light-emitting layer 320 can be in direct contact with the first electrode 310 and the second electrode 330 on the emission area R-EA, G-EA and B-EA of each pixel area PA. The bank insulating layer 160 can include an insulating material. For example, the bank insulating layer 160 can be an organic insulating material. The bank insulating layer 160 can include a different material from the planarization layer 150.

The first electrode 310 of each pixel area PA can be electrically connected to the driving circuit DC of the corresponding pixel area PA. For example, the first electrode 310 of each pixel area PA can be in direct contact with the second source electrode 227 of the corresponding pixel arca PA by penetrating the device passivation layer 140 and the planarization layer 150. The device passivation layer 140 and the planarization layer 150 can include pixel contact holes partially exposing the second source electrode 227 of each pixel area PA. The first electrode 310 of each pixel area PA can be connected to the second source electrode 227 of the corresponding pixel area PA through one of the pixel contact holes. The pixel contact holes can overlap the bank insulating layer 160. Thus, in the display apparatus according to the embodiment of the present disclosure, the change in the location of the first electrode 310 in the emission area R-EA, G-EA and B-EA of cach pixel area PA can be minimized. For example, a portion of the first electrode 310 overlapping with the emission area R-EA, G-EA and B-EA of each pixel area PA can be in direct contact with the upper surface of the planarization layer 150. Therefore, in the display apparatus according to the embodiment of the present disclosure, the luminance deviation according to the generating location of the light emitted from the emission area R-EA, G-EA and B-EA of each pixel area PA can be prevented.

A voltage applied to the second electrode 330 of each pixel area PA can be a same as a voltage applied to the second electrode 330 of adjacent pixel area PA. For example, the second electrode 330 of each pixel area PA can be electrically connected to the second electrode 330 of adjacent pixel area PA. The second electrode 330 of each pixel area PA can include a same material as the second electrode 330 of adjacent pixel area PA. The second electrode 330 of each pixel area PA can be formed by a same process as the second electrode of adjacent pixel area PA. For example, the second electrode 330 of each pixel area PA can be formed simultaneously with the second electrode 330 of adjacent pixel area PA. The second electrode 330 of each pixel area PA can extend beyond the corresponding pixel area PA. For example, the second electrode 330 of each pixel area PA can be in direct contact with the second electrode 330 of adjacent pixel area PA on the bank insulating layer 160. Thus, in the display apparatus according to the embodiment of the present disclosure, a process of forming the second electrode 330 in each pixel area PA can be simplified. And, in the display apparatus according to the embodiment of the present disclosure, the luminance of the light generated by the light-emitting layer 320 of each pixel area PA can be adjusted by the data signal applied to the driving circuit DC of the corresponding pixel arca PA.

The image realized by light emitted from the light-emitting device 300 of each pixel arca PA can include various colors. The light emitted from the light-emitting device 300 of each pixel area PA can display a different color from the light emitted from the light-emitting device 300 of adjacent pixel area PA in a first direction X, as shown in FIGS. 3 and 4. For example, the emission arca R-EA, G-EA and B-EA of cach pixel area PA can be one of a red emission arca R-EA in which red light displaying red color is emitted, a green emission arca G-EA in which green light displaying green color is emitted, and a blue emission arca B-EA in which blue light displaying blue color is emitted, and the red emission areas R-EA, the green emission areas G-EA and the blue emission areas B-EA can be repeated in the first direction X. The light-emitting layer 320 of each pixel arca PA can be spaced apart from the light-emitting layer 320 of adjacent pixel area PA in the first direction X. For example, the light-emitting layer 320 of each pixel area PA can be one of a red light-emitting layer generating the red light, a green light-emitting layer generating the green light and a blue light-emitting layer generating the blue light, and the pixel area PA including the red light-emitting layer, the pixel arca PA including the green light-emitting layer and the pixel arca PA including the blue light-emitting layer can be repeated in the first direction X. The light-emitting layer 320 of each pixel area PA can include a different material from the light-emitting layer 320 of adjacent pixel area PA in the first direction X. The light-emitting layer 320 of each pixel arca PA can have a stacked structure different from the light-emitting layer 320 of adjacent pixel area PA. For example, the light-emitting layer 320 of each pixel area PA can be spaced apart from the light-emitting layer 320 of adjacent pixel area PA in the first direction X on the bank insulating layer 160.

The pixel arcas PA can be disposed side by side in the first direction X and a second direction Y perpendicular to the first direction X. For example, the pixel areas PA can be arranged in a matrix shape. The light emitted from the light-emitting device 300 of each pixel arca PA can display a same color as the light emitted from the light-emitting device 300 of adjacent pixel area PA in the second direction Y. For example, the light-emitting layer 320 of cach pixel arca PA can include a same material as the light-emitting layer 320 of adjacent pixel area PA in the second direction Y. The light-emitting layer 320 of each pixel area PA can have a stacked structure same as the light-emitting layer 320 of adjacent pixel area PA in the second direction Y. The light-emitting layer 320 of each pixel area PA can be spaced apart from the light-emitting layer 320 of adjacent pixel arca PA. For example, the light-emitting layer 320 of each pixel area PA can be spaced apart from the light-emitting layer 320 of adjacent pixel area PA in the second direction Y on the bank insulating layer 160.

An encapsulation structure 400 can be disposed on the light-emitting device 300 of each pixel area PA, as shown in FIGS. 3 to 5. The encapsulation structure 400 can prevent the damage of the light-emitting device 300 in each pixel area PA due to the external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can include an inorganic insulating material, and the second encapsulating layer 420 can include an organic insulating material. Thus, in the display apparatus according to the embodiment of the present disclosure, the damage of the light-emitting device 300 in each pixel area PA due to the external impact and moisture can be effectively prevented. A thickness difference due to the light-emitting device 300 of each pixel area PA can be removed by the second encapsulating layer 420. The second encapsulating layer 420 can have a greater thickness than the first encapsulating layer 410 and the third encapsulating layer 430. For example, an upper surface of the encapsulation structure 400 opposite to the device substrate 100 can be a flat surface.

An optical insulating layer 500 can be disposed on the encapsulation structure 400. The optical insulating layer 500 can include an insulating material. The optical insulating layer 500 can include a transparent material. For example, the optical insulating layer 600 can include an inorganic insulating material and/or an organic insulating material. The optical distance of the light emitted from the light-emitting device 300 of each pixel area PA can be sufficiently secured by the optical insulating layer 500. For example, the optical insulating layer 500 can have a greater thickness than at least one insulating layer 110, 120, 130, 140, 150 and 160 disposed between the device substrate 100 and the encapsulation structure 400. An upper surface of the optical insulating layer 500 opposite to the encapsulation structure 400 can be flat. For example, the upper surface of the optical insulating layer 500 can be parallel to the upper surface of the encapsulation structure 400.

An optical structure 700 can be disposed on the optical insulating layer 500. The optical structure 700 can include optical lenses 710, which are disposed side by side along the upper surface of the optical insulating layer 500. The optical lenses 710 can extend parallel to each other in a direction. For example, in the display apparatus according to the embodiment of the present disclosure, the optical lenses 710 can extend in a direction inclined with the first direction X and the second direction Y. A length of each optical lens 710 can be greater than a length of the emission arca R-EA, G-EA and B-EA defined in each pixel area PA in the first direction X. For example, each of the optical lenses 710 can overlap a plurality of emission areas R-EA, G-EA and B-EA, which are disposed side by side in the first direction X. The light emitted from the light-emitting device 300 of each pixel area PA can be provided to the user through one of the optical lenses 710. A surface of each optical lens 710 opposite to the optical insulating layer 500 can be a curved surface having a convex shape. The image by the light emitted from the light-emitting device 300 of each pixel area PA can be three-dimensionally recognized by the user by the optical lenses 710. For example, the optical lenses 710 can be lenticular lenses. The display apparatus according to the embodiment of the present disclosure can be a light-field display apparatus (LFD) providing a three-dimensional image to the user in the light field method using the optical lenses 710.

The optical structure 700 can include color filters 720 disposed between the optical insulating layer 500 and the optical lenses 710. Each of the color filters 720 can include a different material from adjacent color filter 720. For example, the color filters 720 can include red color filters 720R realizing the red color, green color filters 720G realizing the green color, and blue color filters 720B realizing the blue color. The red color filters 720R, the green color filters 720G and blue color filters 720B can be repeated in the first direction X.

Each of the color filters 720 can overlap one of the optical lenses 710. For example, cach of the optical lenses 710 can overlap one of the red color filters 720R, the green color filters 720G and the blue color filters 720B. A surface of each optical lens 710 toward the color filters 720 can be flat. For example, each of the color filters 720 can be in direct contact with one of the optical lenses 710 and the optical insulating layer 500. Thus, in the display apparatus according to the embodiment of the present disclosure, the light emitted from some of the emission arcas R-EA, G-EA and B-EA overlapping with each optical lens 710 can be blocked by the color filter 720 overlapping with the corresponding optical lens 710. For example, in the display apparatus according to the embodiment of the present disclosure, the light emitted from the green emission arca G-EA and the light emitted from the blue emission area B-EA, which overlaps the optical lens 710 disposed on cach red color filter 720R can be blocked by the corresponding red color filter 720R, the light emitted from the red emission arca R-EA and the light emitted from the blue emission arca B-EA, which overlaps the optical lens 710 disposed on each green color filter 720G can be blocked by the corresponding green color filter 720B, and the light emitted from the red cmission arca R-EA and the light emitted from the green emission area G-EA, which overlaps the optical lens 710 disposed on cach blue color filter 720B can be blocked by the corresponding bluc color filter 720B. That is, in the display apparatus according to the embodiment of the present disclosure, the red light generated by the light-emitting device 300 of cach red emission arca R-EA can be emitted outside through the optical lenses 710 overlapping with the red color filters 720R, the green light generated by the light-emitting device 300 of each green emission arca G-EA can be emitted outside through the optical lenses 710 overlapping with the green color filters 720G, and the blue light generated by the light-emitting device 300 of each blue emission area B-EA can be emitted outside through the optical lenses 710 overlapping with the blue color filters 720B. Therefore, in the display apparatus according to the embodiment of the present disclosure, a distance between the optical lenses 710 through which the light emitted from the light-emitting device 300 of cach pixel area PA passes can be increased.

A length of each optical lens 710 in the first direction X can be different from a length of cach color filter 720 in the first direction X. For example, the length of each color filter 720 in the first direction X can be greater than the length of each optical lens 710 in the first direction X. Each of the optical lenses 710 can be spaced apart from the adjacent optical lens 710. For example, a boundary between adjacent color filters 720 can be disposed between the optical lenses 710. A black matrix 600 can be disposed on the boundary between adjacent color filters 720. The black matrix 600 can include a material blocking light. For example, the black matrix 600 can include a black dye, such as carbon black. Thus, in the display apparatus according to the embodiment of the present disclosure, the boundary between adjacent color filters 720 can't be recognized by the user. An end of cach color filter 720 can be disposed between the optical insulating layer 500 and the black matrix 600. For example, each of the optical lenses 710 can be in contact with a side surface of the black matrix 600. The black matrix 600 can extend parallel to the optical lenses 710 and the color filters 720.

The optical structure 700 can include a lens planarization layer 730 disposed on the optical lenses 710. The curved surface having a convex shape in each optical lens 710 can be covered by the lens planarization layer 730. The lens planarization layer 730 can in direct contact with the curved surface having a convex shape in each optical lens 710. The lens planarization layer 730 can include an insulating material. For example, the lens planarization layer 730 can include an inorganic insulating material and/or an organic insulating material. A thickness difference due to the optical lenses 710 can be removed by the lens planarization layer 730. For example, an upper surface of the lens planarization layer 730 opposite to the optical insulating layer 500 can be flat. A refractive index of the lens planarization layer 730 can be smaller than a refractive index of each optical lens 710. Thus, in the display apparatus according to the embodiment of the present disclosure, the reflection of the light due to the difference in the refractive index can be prevented at a boundary between each optical lens 710 and the lens planarization layer 730. Therefore, in the display apparatus according to the embodiment of the present disclosure, the decrease in the light extraction efficiency due to the boundary between each optical lens 710 and the lens planarization layer 730 can be prevented.

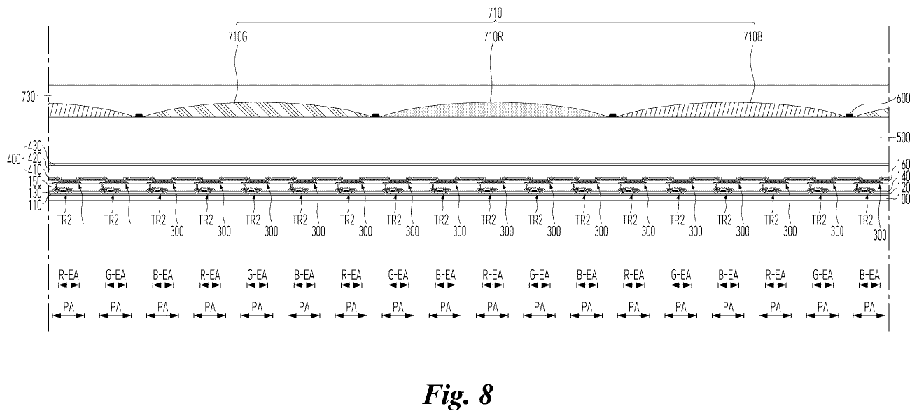

FIG. 6A is a graph showing the location in which the light emitted from a single light-emitting device 300 is recognized in a comparative display apparatus including the optical lenses 710 directly contacting the optical insulating layer 500. FIG. 6B is a graph showing the location in which the light emitted from a single light-emitting device 300 is recognized in the display apparatus according to the embodiment of the present disclosure.

The light emitted from a single light-emitting device 300 is recognized at the front and at an angle of about 15° in the comparative display apparatus (see FIG. 6A), but the light emitted from a single light-emitting device 300 can be recognized at the front and at an angle of about 45° in the display apparatus according to the embodiment of the present disclosure (see FIG. 6B). That is, according to FIG. 6B, in the display apparatus according to the embodiment of the present disclosure, a distance between the optical lenses 710 through which the light emitted from each emission area R-EA, G-EA and B-EA passes can be increased. Thus, in the display apparatus according to the embodiment of the present disclosure as shown in FIG. 6B, a size of an unit image realized by using some of the red emission areas R-EA, some of the green emission arcas G-EA, and some of the blue emission areas B-EA can be increased. Therefore, in the display apparatus of FIG. 6B according to the embodiment of the present disclosure, the FOV region in which the image by a combination of unit images is three-dimensionally recognized by the user can be increased.

Accordingly, the display apparatus according to the embodiment of the present disclosure can include the light-emitting devices 300 on the emission areas R-EA, G-EA and B-EA, the optical insulating layer 500 disposed on the light-emitting devices 300, the color filters 720 disposed on the optical insulating layer 500, and the optical lenses 710 disposed on the color filters 720, wherein cach of the color filters 720 can include a different material from adjacent color filter 720, wherein a plurality of emission areas R-EA, G-EA and B-EA adjacent in the first direction X can overlap a single optical lens 710, and wherein each of the optical lenses 710 can overlap one of the color filters 720. Thus, in the display apparatus according to the embodiment of the present disclosure, a distance between the optical lenses 710 through which the light emitted from a single emission arca R-EA, G-EA and B-EA passes can be increased. Therefore, in the display apparatus according to the embodiment of the present disclosure, the FOV region in which the image is three-dimensionally recognized by the user may be increased, without the decrease in a thickness of the optical insulating layer 500.

And, in the display apparatus according to the embodiment of the present disclosure, the distance between the optical lenses 710 through which the light emitted from each emission arca R-EA, G-EA and B-EA passes can be increased by the color filters 720 disposed between the optical insulating layer 500 and the optical lenses 710. Thus, in the display apparatus according to the embodiment of the present disclosure, a process for providing a three-dimensional image to the user can be simplified. Therefore, in the display apparatus according to the embodiment of the present disclosure, the production energy can be reduced by the process optimization.

The display apparatus according to the embodiment of the present disclosure is described that the driving circuit DC of each pixel area PA can consist of the first thin film transistor TR1, the second thin film transistor TR2 and the storage capacitor Cst. However, in the display apparatus according to another embodiment of the present disclosure, the driving circuit DC of each pixel arca PA can include a driving thin film transistor and at least one switching thin film transistor. For example, in the display apparatus according to another embodiment of the present disclosure, the driving circuit DC of each pixel area PA can further include a third thin film transistor capable of initializing the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor material. The third gate electrode of each pixel area PA can be electrically connected to the corresponding gate line GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in configuring each driving circuit DC can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of cach thin film transistor TR1 and TR2 can be improved.

The display apparatus according to the embodiment of the present disclosure is described that the emission area R-EA, G-EA and B-EA of each pixel area PA can display a same color as the emission area R-EA, G-EA and B-EA of adjacent pixel area PA in the second direction Y. However, in the display apparatus according to another embodiment of the present disclosure, the emission areas R-EA, G-EA and B-EA can be arranged in various ways. For example, in the display apparatus according to the embodiment of the present disclosure, the emission areas R-EA, G-EA and B-EA can be arranged in a pen-tile shape. The red emission areas R-EA and the blue emission areas B-EA can be repeated in the second direction Y. The red emission areas R-EA and the green emission areas G-EA or the blue emission areas B-EA and the green emission areas G-EA can be repeated in the first direction X. Thus, in the display apparatus according to another embodiment of the present disclosure, the degree of freedom for the arrangement of the emission areas R-EA, G-EA and B-EA can be improved.

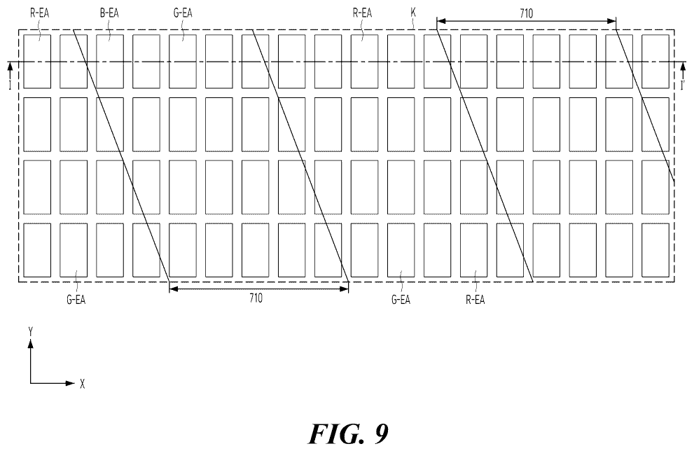

The display apparatus according to the embodiment of the present disclosure is described that the color filters 720 can be disposed between the optical insulating layer 500 and the optical lenses 710. However, in the display apparatus according to another embodiment of the present disclosure, the color filters 720 and the optical lenses 710 can be arranged in various ways. For example, in the display apparatus according to another embodiment of the present disclosure, the lens passivation layer 730 can be disposed on the optical insulating layer 500, the optical lenses 710 and the color filters 720 can be disposed on the lens planarization layer 730, and a surface of each optical lens 710 toward the optical insulating layer 730 can have a convex shape, as shown in FIG. 7. Thus, in the display apparatus according to another embodiment of the present disclosure, the light emitted from some of plurality of emission areas R-EA, G-EA and B-EA overlapping with each optical lens 710 can be blocked by the color filter 720 disposed on the corresponding optical lens 710. Therefore, in the display apparatus according to another embodiment of the present disclosure, the degree of freedom for the location of the optical lenses 710 and the color filters 720 can be improved.

In the display apparatus according to another embodiment of the present disclosure, a cover substrate 800 can be disposed on the color filters 720. The cover substrate 800 can include a transparent material. The cover substrate 800 can include an insulating material. For example, the cover substrate 800 can include glass or plastic. Thus, in the display apparatus according to another embodiment of the present disclosure, the damage of the color filters 720 due to the external impact can be prevented.

The lens planarization layer 730 can include an adhesive material. For example, in the display apparatus according to another embodiment of the present disclosure, the cover substrate 800 in which the red color filters 720R, the green color filters 720G, the blue color filters 720B, the black matrix 600 and the optical lenses 710 are formed can be coupled with the device substrate 100 in which the optical insulating layer 500 by the lens planarization layer 730. That is, in the display apparatus according to another embodiment of the present disclosure, a process of forming the red color filters 720R, the green color filters 720G, the blue color filters 720B, the black matrix 600 and the optical lenses 710 can be independently performed from a process of forming the light-emitting devices 300. Thus, in the display apparatus according to another embodiment of the present disclosure, the damage of the light-emitting devices 300 due to the process of forming the red color filters 720R, the green color filters 720G, the blue color filters 720B, the black matrix 600 and the optical lenses 710 can be prevented. Therefore, in the display apparatus according to another embodiment of the present disclosure, the production energy can be effectively reduced by the process optimization.

The display apparatus according to the embodiment of the present disclosure is described that the optical structure 700 can include the optical lenses 710 and the color filters 720. However, in the display apparatus according to another embodiment of the present disclosure, the color filters 720 can be omitted. For example, in the display apparatus according to another embodiment of the present disclosure, at least one of dye and pigment can be dispersed in each optical lens 710, as shown in FIG. 8. Thus, in the display apparatus according to another embodiment of the present disclosure, the light passing through each optical lens 710 can display a specific color. And, in the display apparatus according to another embodiment of the present disclosure, only the light having a specific wavelength range among the light emitted from a plurality of emission areas R-EA, G-EA and B-EA overlapping with cach optical lens 710 can pass through the corresponding optical lens 710.

The light passing through cach optical lens 710 can display a different color from the light passing through adjacent optical lens 710. Thus, in the display apparatus according to another embodiment of the present disclosure, a distance between the optical lenses 710 through which the light emitted from a single emission area R-EA, G-EA and B-EA passes can be increased by the dye and/or the pigment dispersed in each optical lens 710. Therefore, in the display apparatus according to another embodiment of the present disclosure, the FOV region in which the image is three-dimensionally recognized by the user can be effectively increased. And, in the display apparatus according to another embodiment of the present disclosure, the production energy can be further reduced by the process optimization.

The display apparatus according to the embodiment of the present disclosure is described that the black matrix 600 can be disposed between the optical lenses 710. However, in the display apparatus according to another embodiment of the present disclosure, each of the optical lenses 710 can be in direct contact with adjacent optical lens 710, as shown in FIG. 9. For example, in the display apparatus according to another embodiment of the present disclosure, the length of each optical lens 710 in the first direction X can be the same as the length of the color filter overlapping with the corresponding optical lens 710 in the first direction X. Thus, in the display apparatus according to another embodiment of the present disclosure, the decrease in the quality of the image due to the black matrix can be prevented. For example, in the display apparatus according to another embodiment of the present disclosure, the occurrence of moire due to the repetitive shape of the black matrix can be prevented. Therefore, in the display apparatus according to another embodiment of the present disclosure, the quality of the image three-dimensionally recognized by the user can be improved.

In the result, the display apparatus according to the embodiments of the present disclosure can comprise the light-emitting devices disposed on the emission areas of the device substrate, the optical insulating layer disposed on the light-emitting devices, the color filters disposed on the optical insulating layer, and the optical lenses disposed on the color filters, wherein the light emitted from each emission area can display a different color from the light emitted from adjacent emission area, wherein each of the color filters can overlap a plurality of emission areas, and wherein each of the optical lenses can overlap one of the color filters. Thus, in the display apparatus according to the embodiments of the present disclosure, the light emitted from some of the plurality of emission areas overlapping cach optical lens can be blocked by the color filter overlapping with the corresponding optical lens. That is, in the display apparatus according to the embodiments of the present disclosure, the distance between the optical lenses through which the light emitted from each light-emitting device passes can be increased. Thereby, in the display apparatus according to the embodiments of the present disclosure, the FOV region in which the image is three-dimensionally recognized by the user can be increased. And, in the display apparatus according to the embodiments of the present disclosure, the production energy can be reduced by the process optimization.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly. the claims are not limited by the disclosure.

1. A display apparatus comprising:
a first light-emitting device on a first emission area of a device substrate;
a second light-emitting device on a second emission area of the device substrate;
an optical insulating layer on the first light-emitting device and the second light-emitting device; and
an optical structure on the optical insulating layer, the optical structure including a first curved surface of a convex shape overlapping with the first emission area and the second emission area,
wherein the light emitted from the second emission area displays a different color from the light emitted from the first emission area, and
wherein the optical structure includes at least one of dye and pigment.

2. The display apparatus according to claim 1, wherein the light passing through the optical structure displays a same color as the light emitted from the first emission area.

3. The display apparatus according to claim 1, wherein the optical structure includes a first optical lens having the first curved surface, and
wherein the dye and the pigment are dispersed in the first optical lens.

4. The display apparatus according to claim 3, wherein the optical structure includes a lens planarization layer covering the first curved surface of the first optical lens, and
wherein the refractive index of the lens planarization layer is smaller than the refractive index of the first optical lens.

5. The display apparatus according to claim 3, further comprising a third light-emitting device disposed between a third emission area of the device substrate and the optical insulating layer,
wherein the optical insulating layer includes a second optical lens overlapping with the third emission area, the second optical lens having a second curved surface of a shape same as the first curved surface, and
wherein the light passing through the second optical lens displays a different color from the light passing through the first optical lens.

6. The display apparatus according to claim 5, wherein the light emitted from the third emission area displays a different color from the light emitted from the first emission area and the light emitted from the second emission area, and
wherein the light passing through the second optical lens displays a same color as the light emitted from the second emission area.

7. The display apparatus according to claim 5, further comprising a black matrix disposed between the first optical lens and the second optical lens.

8. The display apparatus according to claim 1, wherein the first curved surface has a convex shape toward a direction opposite to the device substrate.

9. A display apparatus comprising:
light-emitting devices on emission areas of a device substrate;
an optical insulating layer on the light-emitting devices;
a color filter on the optical insulating layer, the color filter overlapping with the emission areas from a plan view; and
an optical lens on the optical insulating layer, the optical lens overlapping with the color filter from a plan view,
wherein the light generated by each light-emitting device displays a different color from the light generated by adjacent light-emitting device, and
wherein the light passing through the color filter displays a same color as the light generated by one of the light-emitting devices.

10. The display apparatus according to claim 9, wherein a surface of the optical lens toward the color filter is in contact with the color filter.

11. The display apparatus according to claim 9, wherein the emission areas are disposed side by side in a first direction and a second direction perpendicular to the first direction, and
wherein the color filter and the optical lens extend parallel to each other in a direction inclined with the first direction and the second direction.

12. The display apparatus according to claim 9, wherein the length of the color filter in the first direction is different from the length of the optical lens in the first direction.

13. The display apparatus according to claim 9, further comprising a lens planarization layer disposed between the optical insulating layer and the optical lens,
wherein the optical lens disposed between the lens planarization layer and the color filter has a curved surface of a convex shape contacting with the lens planarization layer, and
wherein the refractive index of the lens planarization layer is smaller than the refractive index of the optical lens.

14. The display apparatus according to claim 13, further comprising a cover substrate on the color filter.

15. The display apparatus according to claim 9, wherein a region disposed between the emission areas overlaps a portion of the optical lens.

16. A display apparatus comprising:
a first light-emitting device on a first emission area of a device substrate;
a second light-emitting device on a second emission area of the device substrate;
an optical insulating layer on the first light-emitting device and the second light-emitting device;
a color filter on the optical insulating layer; and
an optical lens on the optical insulating layer, the optical lens overlapping the color filter from a plan view,
wherein the light emitted from the second emission area displays a different color from the light emitted from the first emission area.

17. The display apparatus according to claim 16, wherein a surface of the optical lens toward the color filter is in contact with the color filter.

18. The display apparatus according to claim 16, wherein the length of the color filter in the first direction is different from the length of the optical lens in the first direction.

19. The display apparatus according to claim 16, further comprising a lens planarization layer disposed between the optical insulating layer and the optical lens,
wherein the optical lens disposed between the lens planarization layer and the color filter has a curved surface of a convex shape contacting with the lens planarization layer, and
wherein the refractive index of the lens planarization layer is smaller than the refractive index of the optical lens.
